(19) United States
(12) Patent Application Publication
(10) Pub. No.: US 2009/0041935 A1
(43) Pub. Date: Feb. 12, 2009

(54) METHOD FOR CAUSING PARTICULATE BASE MATERIAL TO CARRY ALLOY PARTICLE

(76) Inventors: Mutsuki Yamazaki, Yokohama-shi (JP); Kohei Nakayama, Kawasaki-shi (JP); Yoshihiko Nakano, Yokohama-shi (JP); Wu Mei, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/187,697

(22) Filed: Aug. 7, 2008

(30) Foreign Application Priority Data
Aug. 10, 2007 (JP) P2007-209837

(51) Int. Cl. C23C 16/06

(52) U.S. Cl. 427/191; 118/716

(57) ABSTRACT

A method is for causing, within a decompression device, a particulate base material to carry an alloy particle having a particle size smaller than that of the particulate base material, the alloy particle containing at least two elements, the method including: forming the particulate base material by a chemical deposition; causing, in the decompression device, the particulate base material to carry a microparticle element; and forming the alloy particle by alloying the particulate base material and the microparticle element.

### RELATED APPLICATION(S)

The present disclosure relates to the subject matter contained in Japanese Patent Application No. 2007-209837 filed on Aug. 10, 2007, which is incorporated herein by reference in its entirety.

### FIELD

The present invention relates to a method and apparatus for allowing a particulate carrier having a particulate size of 1 μm or less to carry a microparticle having a particle size of 10 nm or less, and more particularly to a method for manufacturing a catalyst that can be utilized for a direct methanol fuel cell (DMFC).

### BACKGROUND

A noble metal such as platinum is used as a chemical catalyst as well as jewelry. For example, noble metal is used in an exhaust gas purifier of a vehicle, a polymer electrolyte fuel cell (PEFC). Since the polymer electrolyte fuel cell using a methanol solution as a fuel can be operated at a low temperature and has a small size and weight, the polymer electrolyte fuel cell has recently been vigorously researched in order to utilize the fuel cell as a power supply to be mounted on a small device such as a mobile device. However, a further improvement in performance has been desired to widely utilize the polymer electrolyte fuel cell. Since a fuel cell serves to convert a chemical energy generated by an electrocatalytic reaction into electrical power, a high active catalyst is indispensable to the improvement in performance.

Presently, an alloy of platinum and ruthenium (which will be hereinafter referred to as “platinum-ruthenium”) is generally used as an anode catalyst of a fuel cell. However, while the fuel cell has a theoretical voltage of the electrocatalytic reaction of 1.21 V, a voltage loss by the platinum-ruthenium catalyst is approximately 0.3 V and is comparatively large. In order to reduce the voltage loss, an anode catalyst having a high activity (a methanol oxidation activity) exceeding the platinum-ruthenium has been required. In order to improve the methanol oxidation activity, there has been considered to add another element to the platinum-ruthenium alloy.

In a conventional sputtering method or evaporating method, generally, a catalytic microparticle is carried on a carbon sheet (which will be hereinafter referred to as a “carbon paper”). In this case, the evaporation is performed over only a surface of the carbon paper. Therefore, in the case in which the catalytic microparticle having a size of several nanometers is to be carried, a necessary carrying amount for a power generation cannot be obtained. Moreover, in some cases, an alloy serving as a catalyst does not form a microparticle but be formed as a thin film depending on an evaporating condition. In those cases, there is a drawback that total surface area of the catalyst is reduced and a power generating performance is largely deteriorated.

On the other hand, there is known a technique that a catalytic metal is evaporated or sputtered on a carrier particulate to carry a catalytic microparticle. An example of such technique is disclosed in JP-A-2005-264297 (counterpart U.S. publication is: US 2007/0213212 A1).

In the case in which a carbon particle is used as a carrier in the above described method, carbon powder is sputtered or evaporated while the carbon powder is stirred. In this case, even if an observation is performed through an electron microscope, a substance other than the carbon cannot be found. The reason is that a surface condition of a carbonic microparticle which is a substance to be evaporated and an evaporated atom relate to a process for forming a metallic microparticle. More specifically, in the case in which a metal is physically evaporated in a vacuum process, a thermal or kinetic energy is utilized to cause an evaporating substrate to fly like an atom and to collide with the evaporated substance. Therefore, the evaporating atom performs a migration (a free movement over a carrier surface) and is fixed to a stable place on an energy basis, and particles then grow by setting the place to be a nucleus and are bonded to form a polycrystalline film.

In a case of a carbonic microparticle having a particle size of 1 μm or less, however, a large number of defects are present on a surface. For this reason, a distance at which the evaporated atom can perform the migration is very short and there is a low probability that a necessary nucleus for a grain growth might be formed. Accordingly, in the case in which carbon powder is evaporated while stirred, the powder is moved before the nucleus is formed so that the evaporated substance does not fly. For this reason, the evaporated substance is stuck as an atom onto the surface so that a nucleation as well as the grain growth is not caused. Although a microparticle having a particle size which is equal to or greater than 2 nm and is equal to or smaller than 10 nm is to be carried on the surface of the carbon powder in order to function as a catalyst, it is unable to expect that the function of the catalyst is exhibited because the metallic atom is stuck onto the carrier surface.

### SUMMARY

According to a first aspect of the invention, there is provided a method for causing, within a decompression device, a particulate base material to carry an alloy particle having a particle size smaller than that of the particulate base material, the alloy particle containing at least two elements, the method including: forming the particulate base material by a chemical deposition; causing, in the decompression device, the particulate base material to carry a microparticle element; and forming the alloy particle by alloying the particulate base material and the microparticle element.

According to a second aspect of the invention, there is provided an apparatus that causes, within a decompression device, a particulate base material to carry an alloy particle having a particle size smaller than that of the particulate base material, the alloy particle containing at least two elements, the apparatus including: a first container that accommodates the particulate base material; a second container that accommodates the first container and is capable of being depressurized; a third container that has a mechanism for vaporizing an element to be contained in the alloy particle; and a mechanism that moves the first container from the second container to the third container under depressurized environment.

### BRIEF DESCRIPTION OF THE DRAWINGS

In the accompanying drawings:

FIGS. 1A and 1B are conceptual views for explaining the present invention;

FIG. 2 is a schematic sectional view showing an example of a microparticle carrying apparatus which is usable in the present invention;

FIG. 3 is a schematic sectional view showing an example of the microparticle carrying apparatus which is usable in the present invention;

FIG. 4 is a schematic sectional view showing an example of the microparticle carrying apparatus which is usable in the present invention;

FIG. 5 is a schematic sectional view showing a film and electrode complex according to an example of the present invention; and

FIG. 6 is a schematic sectional view showing a single cell of a direct methanol fuel cell according to the example of the present invention.

### DETAILED DESCRIPTION OF THE EMBODIMENTS

Hereinafter, embodiments of the invention will be described.

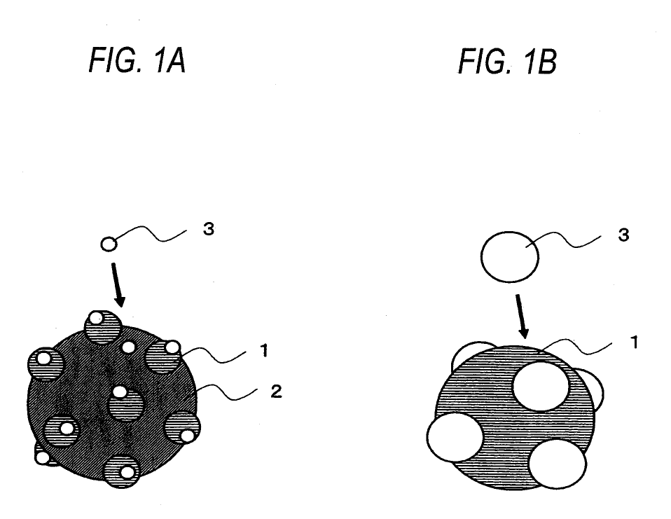

A microparticle carrying method according to the present invention serves to carry an alloy of metals containing at least two elements on a surface of a particulate base material, and to add a microparticle element 3 to be alloyed with platinum or a platinum-ruthenium alloy 1 and to enhance a catalytic activity to a particulate base material 2 containing, as a main body, carbon carrying the platinum or platinum-ruthenium alloy 1 through a chemical deposition in a decompression device as shown in FIG. 1A. By the method, it is possible to form an alloy particle within a predetermined particle size range on the surface of the particulate base material. As shown in FIG. 1B, the particulate base material may be a platinum-ruthenium alloy having an average particle size of 150 nm or less.

In the case in which the particulate base material carrying the platinum or platinum-ruthenium alloy through the chemical deposition is inserted into the decompression device as described above, adsorbed water or carbon dioxide vaporizes so that a degree of vacuum in the device is greatly reduced. In the case in which sputtering is performed in that condition, moreover, it is necessary to sufficiently increase the degree of vacuum. However, it is necessary to slowly execute an exhaust because there is a possibility that the particulate base material might be scattered in the device. As a result, a time required for the exhaust is increased so that productivity is deteriorated.

In a microparticle carrying apparatus according to the invention, therefore, it is possible to reduce a pressure in a first container for accommodating a particulate base material, to insert the first container into a second container in which a pressure can be reduced, to reduce the pressure in the second container, and to then open a cover of the first container. The first container having the cover opened has a mechanism which can be moved into a third container including a sputtering device with a pressure reduced. The moving mechanism can be moved through a manual push-pull between the second and third containers with the first container mounted thereon, and may be a pedestal having a belt conveyer or a wheel. According to the structure as described above, the particulate base material can be prevented from being scattered and an efficient production can be performed.

After the sputtering is executed, the first container is moved again from the third container to the second container and is covered in air tightness. When the second container is returned to have an atmospheric pressure with an inert gas and the first container is taken out, an alloy particle in the container is maintained under pressure reduction. When heating is performed up to a temperature which is equal to or higher than 100 degrees Celsius and is equal to or lower than 400 degrees Celsius, preferably, is equal to or lower than 300 degrees Celsius while stirring is executed, then, the sputtered microparticle element and the platinum or platinum-ruthenium alloy carried on the particulate base material through the chemical deposition are further advanced to be alloyed so that a high activity can be obtained.

In the process, in some cases in which the particulate base material once comes in contact with the air, it is easily burned. In the case in which the particulate base material is burned, the chemically deposited ruthenium is oxidized. Therefore, the catalytic activity is considerably deteriorated. In the carrying apparatus according to the invention, the first container accommodating the particulate base material is covered in air tightness in a vacuum device after the creation of a catalyst and is then taken out. Therefore, there is no possibility that the particulate base material might be burned.

In the case in which a film and electrode complex (MEA) or a single cell which will be described below is formed, it is necessary to perform the forming work in an environment having an oxygen concentration of 1% or less. Preferably, it is necessary to add water to the particulate base material or to execute a step of forming a proton conducting material such as Nafion (registered trademark; produced by DuPont Co., Ltd.) in a glove box filled with nitrogen. By the operation, it is possible to safely obtain an electrode for a power generating device which uses a catalyst having a high activity.

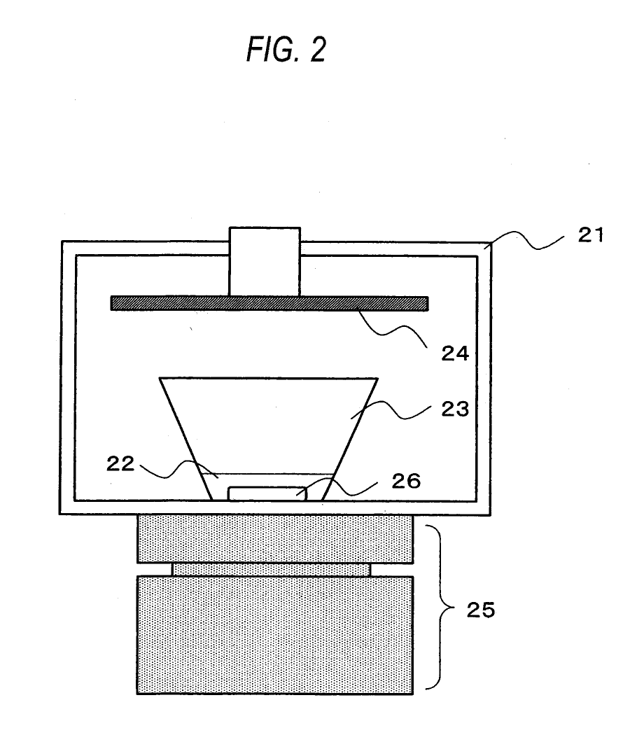

FIG. 2 shows an example of a typical sectional view illustrating a microparticle carrying apparatus employing a sputtering device which is usable in the present invention. In FIG. 2, 21 denotes a vacuum chamber to be a decompression device, and a container 23 accommodating a particulate base material 22 is disposed therein. A microparticle element sputtering target 24 regulating a composition to obtain a desirable composition is disposed above the container 23. A magnetic stirrer 25 is disposed under the container 23 in the vacuum chamber 21, and a magnetic rotor 26 is rotated synchronously with a rotation of the magnetic stirrer 25 to stir the particulate base material disposed in the container 23. The rotation of the magnetic stirrer 25 is controlled to be stopped by a control device which is not shown.

FIG. 2 does not illustrate auxiliary devices that are attached in the sputtering device, for example, a decompression device or a power device. In addition to the deposition of the magnetic stirrer 25, however, it is possible to use the sputtering device which is generally utilized. More specifically, it is possible to use an ion sputtering device, an RF/DC sputtering device or an ECR sputtering device.

While the sputtering device is taken as an example of the device, similarly, it is possible to use a metal evaporating device utilized generally in place of the sputtering device by disposing the magnetic stirrer. By using the device for carrying an alloy particle on the surface of the particulate base material to drive or stop the magnetic stirrer, it is possible to control a time zone in which a relative position of the particulate base material is changed and a time zone in which the same relative position is not changed. Thus, it is possible to obtain the particulate base material carrying an alloy particle which has a predetermined particle size.

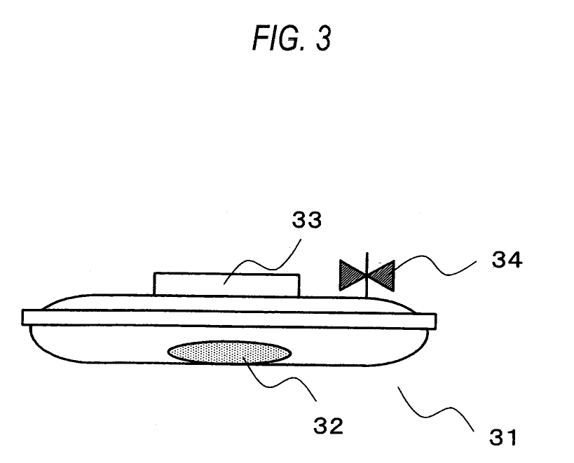

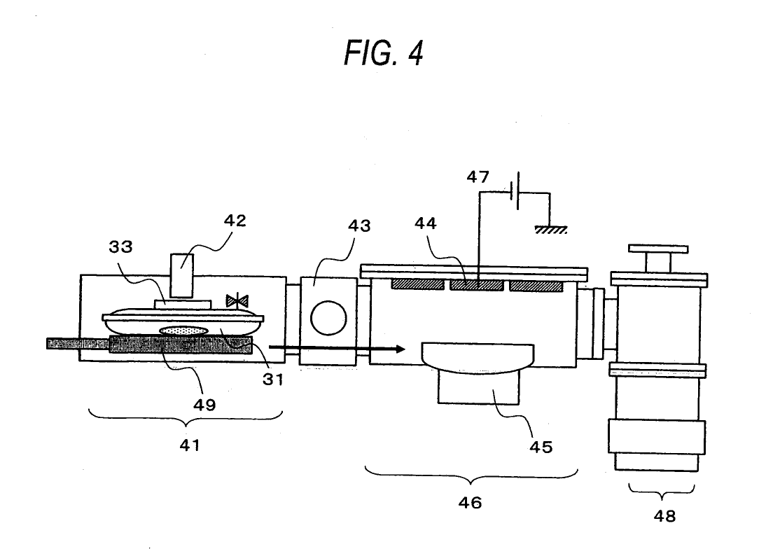

FIGS. 3 and 4 show an example of typical sectional views illustrating the microparticle carrying apparatus which is usable in the invention. A particulate base material and a magnetic rotor 32 for stirring the particulate base material are accommodated in a first container 31, and a cover 33 is put in air tightness and a valve 34 attached to the cover 33 is then connected to a vacuum pump which is not shown, and a pressure is thus reduced. Thereafter, the valve 34 is closed and disconnected from the vacuum pump.

After a particulate base material containing carbon as a base body is accommodated in the first container 31, a pump is used to discharge air down to 1 Pa or less. In this case, the magnetic rotor 32 provided in the first container 31 is rotated to stir the particulate base material. When heating is performed up to 200 degrees Celsius or less, preferably, 150 degrees Celsius or less, degassing can be performed more quickly. As shown in FIG. 4, thereafter, the first container 31 is put in a second container 41 and air in the second container 41 is discharged down to 1 Pa or less by means of a vacuum pump 48. Next, the cover 33 of the first container 31 is lifted through an up-down jig 42 and is thus opened. By executing the opening operation under pressure reduction, it is possible to prevent the particulate base material from being soared.

Subsequently, a gate valve 43 is opened and a microparticle element sputtering target 44 is disposed and moved by using a moving mechanism 49 to a third container 46 to be a sputtering chamber which includes a magnet stirrer 45, and a power of 1 kW is supplied from a power supply 47 to the microparticle element sputtering target 44 to perform sputtering. The power supply may be a DC power supply or a high frequency power supply of 13.56 MHz. In the case in which the high frequency power supply is used, a matching box is put between the power supply and an alloy sputtering target to regulate impedance. Thus, a high degree of vacuum can be obtained in a short time and an efficient production can be implemented. By previously performing the stirring operation for a sufficient time while discharging air from an inner part of the first container through the vacuum pump 48, moreover, the coagulated particulate base material is separated and can be caused to carry a microparticle element uniformly.

### FIRST EXAMPLE

The container 23 accommodating 50 g of a particulate base material containing carbon as a base body in which a carrying rate (weight % of a catalyst to the particulate base material) of a platinum-ruthenium alloy (50 atom % of platinum and 50 atom % of ruthenium) is 40%, an average particle size is equal to or smaller than 150 nm, and a surface area is equal to or larger than 150 m²/g was put under the microparticle element sputtering target 24 containing tungsten and niobium, and sputtering was performed for 10 hours with RF Power : 1 kw, an Ar flow rate of 50 CCM and a pressure of 1×10⁻² Pa. The magnetic rotor 26 formed of Teflon (registered trademark; produced by DuPont Co., Ltd.) and put previously in the container was rotated by means of the magnetic stirrer 25 disposed on an outside of the vacuum chamber 21 to stir the particulate base material during the sputtering. By the operation, there was obtained 100 g of the particulate base material having a carrying rate (a weight of a catalyst to that of the carbon) of 50%.

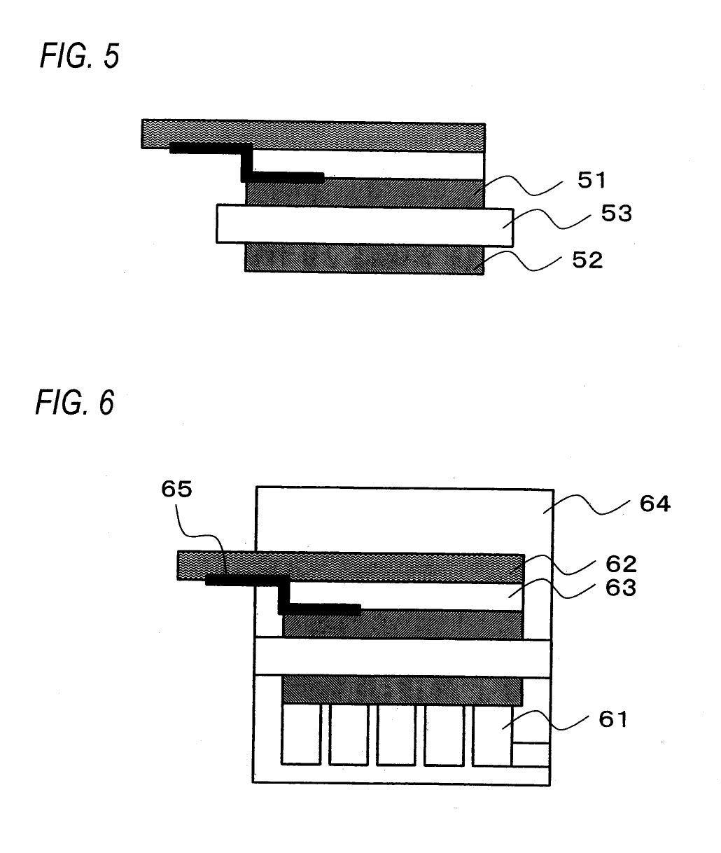

FIG. 5 is a typical view showing a film and electrode complex for catalytic evaluation according to the examples. FIG. 6 is a typical view showing a single cell of a direct methanol fuel cell incorporating the film and electrode complex. By using the particulate base material thus obtained, a cathode electrode 51 and an anode electrode 52 were produced respectively and were subjected to thermo-compression bonding at 125 degrees Celsius for 10 minutes at a pressure of 30 kg/cm² with a proton conducting solid polymer film 53 formed of Nafion (registered trademark; produced by DuPont Co., Ltd.) which is interposed between the cathode electrode 51 and the anode electrode 52 so that a film and electrode complex (MEA) was produced. By using the film and electrode complex, and a channel plate 61, a fuel penetrating portion 62, a vaporizing portion 63, a separator 64 and a lead wire 65, the single cell of the direct methanol fuel cell was produced. In the single cell, a 1 M methanol solution to be a fuel was supplied in a flow rate of 0.6 ml/min to the anode electrode and air was supplied in a flow rate of 200 ml/minute to the cathode electrode, and a discharge was performed to maintain a current density of 150 mA/cm² in a state in which the cell was maintained at 65 degrees Celsius, and a cell voltage was measured after 30 minutes. Consequently, a voltage of 0.6 V was obtained. The voltage thus obtained had a greater value by 20% or more as compared with the case in which the single cell was produced in an equal amount of a noble metal. In the case in which the single cell is produced through a vacuum process, thus, the sputtered ruthenium is not oxidized. Therefore, it is possible to suppose that a small elution is generated through formic acid in a power generating process, an alloy particle is stably formed on the particulate base material and deterioration in a characteristic in use for a long period of time is reduced. After the measurement of a cell voltage, an average particle size of the alloy particle was measured to be 4 nm.

### SECOND EXAMPLE

In the following examples, points different from the first example will be mainly described, and description of other identical points to the first example will be omitted.

Nickel and silicon were used for a microparticle element sputtering target to obtain a particulate base material, and a single cell was produced to measure a voltage on the same condition. The voltage thus obtained had a greater value by 20% or more as compared with the case in which the single cell was produced in an equal amount of a noble metal. An average particle size of an alloy particle was 4 nm.

### THIRD EXAMPLE

Vanadium and niobium were used for a microparticle element sputtering target to obtain a particulate base material, and a single cell was produced to measure a voltage on the same condition. The voltage thus obtained had a greater value by 20% or more as compared with the case in which the single cell was produced in an equal amount of a noble metal. An average particle size of an alloy particle was 4 nm.

### FOURTH EXAMPLE

Tungsten and molybdenum were used for a microparticle element sputtering target to obtain a particulate base material, and a single cell was produced to measure a voltage on the same condition. The voltage thus obtained had a greater value by 20% or more as compared with the case in which the single cell was produced in an equal amount of a noble metal. An average particle size of an alloy particle was 4 nm.

### FIFTH EXAMPLE

Tungsten and titanium were used for a microparticle element sputtering target to obtain a particulate base material, and a single cell was produced to measure a voltage on the same condition. The voltage thus obtained had a greater value by 20% or more as compared with the case in which the single cell was produced in an equal amount of a noble metal. An average particle size of an alloy particle was 4 nm.

### SIXTH EXAMPLE

Tungsten and chromium were used for a microparticle element sputtering target to obtain a particulate base material, and a single cell was produced to measure a voltage on the same condition. The voltage thus obtained had a greater value by 20% or more as compared with the case in which the single cell was produced in an equal amount of a noble metal. An average particle size of an alloy particle was 4 nm.

### SEVENTH EXAMPLE

By using the microparticle carrying apparatus shown in FIGS. 3 and 4, an alloyed microparticle carrying particulate base material was manufactured. There was accommodated carbon in 50 g of a particulate base material containing the carbon as a base body and having a carrying rate of 40% at which a platinum -ruthenium alloy was carried on the first container 51, an average particle size of 150 nm or less and a surface area of 150 m²/g or more, and a particulate carrier was stirred. Tungsten and titanium were used for a microparticle element sputtering target to obtain a particulate base material, and a single cell was produced to measure a voltage on the same condition. The voltage thus obtained had a greater value by 20% or more as compared with the case in which the single cell was produced in an equal amount of a noble metal. An average particle size of an alloy particle was 4 nm.

### EIGHT EXAMPLE

In the same manner as in the seventh example, tungsten and titanium were sputtered, for ten hours, onto a particulate base body having a platinum-ruthenium alloy deposited chemically, and the first container was then moved from the third container to the second container and the cover was brought downward by means of an up-down jig so that the first container was hermetically closed. Thereafter, the second container was returned to have an atmospheric pressure and the first container was taken out, and heating was performed for two hours at a temperature of 250 degrees Celsius while performing stirring over a magnet stirrer. Consequently, it is possible to heat the particulate base material without coming in contact with the air. Therefore, an added element was alloyed progressively so that a higher characteristic could be obtained. An average particle size of an alloy particle thus obtained was 4 nm.

### NINTH EXAMPLE

In the same manner as in the seventh example, nickel and silicon were sputtered, for ten hours, onto a particulate base body having a platinum-ruthenium alloy deposited chemically, and the first container was then moved from the third container to the second container and the cover was brought downward by means of an up-down jig so that the first container was hermetically closed. Thereafter, the second container was returned to have an atmospheric pressure and the first container was taken out, and heating was performed for two hours at a temperature of 250 degrees Celsius while performing stirring over a magnet stirrer.

Air was previously discharged from an inner part of the first container by means of a pump, and at the same time, the particulate base material was stirred for a sufficient period of time so that a coagulated carrier was separated. Consequently, it was possible to uniformly carry an alloy particle formed of nickel and silicon and having an average particle size of 4 nm. At this time, a part of the alloy particle was alloyed with a platinum-ruthenium alloyed microparticle, and a catalytic activity was enhanced by 30% or more as compared with the case in which neither nickel nor silicon is added. Moreover, a catalyst having an activity enhanced was often exposed to air and burned. By using the apparatus according to the invention, however, the first container accommodating the particulate base material is covered in air tightness in the vacuum device after the fabrication and is then taken out. Therefore, the catalyst was prevented from being burned. An average particle size of an alloy particle thus obtained was 4 nm.

As described above in detail, there is provided a method and apparatus for causing a particulate base body having a particle size of 1 μm or less to carry a microparticle having a particle size of 10 nm or less, and an application includes a direct methanol fuel cell utilizing the powder for a catalyst.

It is to be understood that the present invention is not limited to the specific embodiment described above and that the invention can be embodied with the components modified without departing from the spirit and scope of the invention. The invention can be embodied in various forms according to appropriate combinations of the components disclosed in the embodiment described above. For example, some components may be deleted from all components shown in the embodiment. Further, the components in different embodiments may be used appropriately in combination.

What is claimed is:

1. A method for causing, within a decompression device, a particulate base material to carry an alloy particle having a particle size smaller than that of the particulate base material, the alloy particle containing at least two elements, the method comprising:
forming the particulate base material by a chemical deposition;
causing, in the decompression device, the particulate base material to carry a microparticle element; and
forming the alloy particle by alloying the particulate base material and the microparticle element.

2. The method according to claim 1, wherein the particulate base material contains carbon.

3. The method according to claim 1, wherein the particulate base material contains at least one of platinum and a platinum-ruthenium alloy.

4. The method according to claim 1, wherein the microparticle element contains at least one element selected from a group including tungsten, molybdenum, titanium, chromium, vanadium, niobium, nickel, and silicon.

5. An apparatus that causes, within a decompression device, a particulate base material to carry an alloy particle having a particle size smaller than that of the particulate base material, the alloy particle containing at least two elements, the apparatus comprising:
a first container that accommodates the particulate base material;
a second container that accommodates the first container and is capable of being depressurized;
a third container that has a mechanism for vaporizing an element to be contained in the alloy particle; and
a mechanism that moves the first container from the second container to the third container under depressurized environment.
